(19) United States
(12) Patent Application Publication
(10) Pub. No.: US 2026/0332083 A1
(43) Pub. Date: Oct. 22, 2026

(54) ELECTRIC MOTOR CONTROL DEVICE AND ELECTRIC MOTOR CONTROL METHOD

(71) Applicant: HITACHI ASTEMO, LTD., Hitachinaka-shi, Ibaraki (JP)

(72) Inventors: Tomio SAKASHITA, Hitachinaka-shi, Ibaraki (JP); Akira ISHII, Hitachinaka-shi, Ibaraki (JP); Susumu KANEKO, Hitachinaka-shi, Ibaraki (JP)

(73) Assignee: HITACHI ASTEMO, LTD., Hitachinaka-shi, Ibaraki (JP)

(21) Appl. No.: 19/111,290

(22) PCT Filed: Jul. 25, 2023
(86) PCT No.: PCT/JP2023/027092

§ 371 Date: Mar. 12, 2025

(30) Foreign Application Priority Data
Sep. 15, 2022 (JP) 2022-146759

(51) Int. Cl. H02P 29/024; B62D 5/04; G01R 31/42; H02P 5/74; H02P 27/06

(52) U.S. Cl. CPC H02P 29/024; B62D 5/046; G01R 31/42; H02P 5/74; H02P 27/06

(57) ABSTRACT

An electric motor control device includes a first drive system including a first MCU and a first inverter, and a second drive system including a second MCU and a second inverter. The first MCU controls an electric motor by a first inverter and supplies a current to the first inverter to execute a failure diagnosis. When a failure occurs in the first drive system, the second MCU controls the electric motor by the second inverter connected to an electric path connecting the first inverter and the electric motor, and supplies a current to the second inverter to execute a failure diagnosis. The first MCU executes the failure diagnosis of the first inverter when the current is not supplied to the second inverter. The second MCU executes the failure diagnosis of the second inverter when the current is not supplied to the first inverter.

### TECHNICAL FIELD

The present invention relates to an electric motor control device and to an electric motor control method.

### BACKGROUND ART

When a failure occurs in a drive system of an electric motor that assists a steering force in an electric power steering device for a vehicle, assistance for the steering force provided by the electric motor is suddenly lost. Therefore, as described in WO 2015/129271 A1 (Patent Document 1), an electric motor has multiplexed drive systems. Herein, when controlling an electric motor such as an AC motor, a DC current is converted into an AC current by an inverter configured by connecting a plurality of semiconductor switching elements as appropriate so as to enable a rotation speed and an output torque to be changed freely, and this AC current is supplied to the electric motor.

### REFERENCE DOCUMENT LIST

### Patent Document

Patent Document 1: WO 2015/129271 A1

### SUMMARY OF THE INVENTION

### Problem to be Solved by the Invention

In an inverter in a drive system, whether a disconnection failure has occurred in a semiconductor switching element can be diagnosed in accordance with a voltage upstream of the inverter and an inter-terminal voltage of the electric motor by selectively operating semiconductor switching elements on an upper or a lower stage of the inverter, for example. In a control device having multiplexed drive systems, a current may be supplied simultaneously from the inverter of each of the drive systems to the electric motor for a reason such as fluctuations in execution time of a micro-control unit, for example, when diagnosis processing is executed by activating each of the drive systems. In this case, the electric motor is supplied with an AC current by a normal drive system. Thus, it is erroneously diagnosed that the semiconductor switching elements are normal in a drive system in which a failure has occurred in the semiconductor switching elements.

The present invention therefore has an object to provide an electric motor control device and an electric motor control method that, even in a control device having multiplexed drive systems of an electric motor, make a failure in each of the drive systems less likely to be erroneously diagnosed.

### Means for Solving the Problem

An electric motor control device that controls driving of an electric motor including windings of a plurality of phases, includes a first drive system including a first micro-control unit and a first inverter composed of a plurality of semiconductor switching elements, and a second drive system including a second micro-control unit and a second inverter composed of a plurality of semiconductor switching elements. The first micro-control unit is configured to control the semiconductor switching elements of the first inverter and convert a DC current into an AC current to control driving of the electric motor and to individually supply a current to the plurality of semiconductor switching elements of the first inverter to execute a failure diagnosis of the first inverter. The second inverter is connected to an electric path connecting the first inverter and the electric motor. The second micro-control unit is configured to, when a failure occurs in the first drive system, control the semiconductor switching elements of the second inverter and convert a DC current into an AC current to control driving of the electric motor and to individually supply a current to the plurality of semiconductor switching elements of the second inverter to execute a failure diagnosis of the second inverter. The first micro-control unit is configured to execute the failure diagnosis of the first inverter when the current is not supplied to the plurality of semiconductor switching elements of the second inverter in the second drive system. The second micro-control unit is configured to execute the failure diagnosis of the second inverter when the current is not supplied to the plurality of semiconductor switching elements of the first inverter in the first drive system.

### Effect of the Invention

According to the present invention, even in a control device having multiplexed drive systems of an electric motor, a failure in each of the drive systems can be less likely to be erroneously diagnosed.

### BRIEF DESCRIPTION OF THE DRAWINGS

FIG. 1 is a schematic diagram showing an example of an electric power steering system.

FIG. 2 is a schematic diagram showing an example of a control system of the electric power steering system.

FIG. 3 is a schematic diagram showing an example of a first motor of an electric motor and an inner structure of a first control device.

FIG. 4 is an overall schematic diagram showing an example of a control system of the electric motor.

FIG. 5 is a flowchart showing an example of first diagnosis processing to be executed by the first control device.

FIG. 6 is a flowchart showing an example of the first diagnosis processing to be executed by a third control device.

FIG. 7 is an explanatory diagram of execution timing of diagnoses A and B performed by the first diagnosis processing.

FIG. 8 is a flowchart showing an example of second diagnosis processing to be executed by the first control device.

FIG. 9 is a flowchart showing an example of the second diagnosis processing to be executed by the third control device.

FIG. 10 is an explanatory diagram of execution timing of diagnoses A and B performed by the second diagnosis processing.

FIG. 11 is a flowchart showing an example of third diagnosis processing to be executed by the first control device.

FIG. 12 is a flowchart showing an example of the third diagnosis processing to be executed by the third control device.

### MODE FOR CARRYING OUT THE INVENTION

Hereinafter, embodiments for carrying out the present invention will be described in detail with reference to the appended drawings.

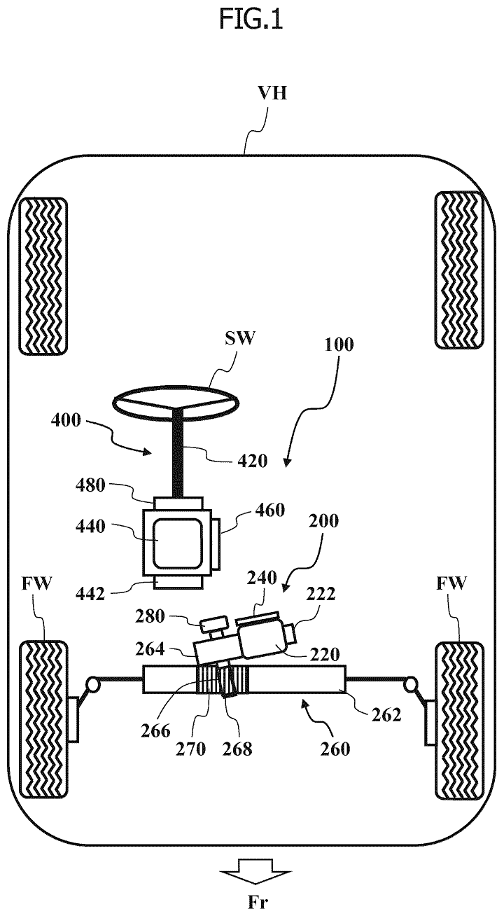

FIG. 1 shows an example of an electric power steering system 100 mounted on a vehicle VH such as an automobile or a construction machine. Herein, Fr in FIG. 1 represents a forward side of the vehicle.

Electric power steering system 100 includes a steering device 200 that steers front wheels FW, which are steered wheels, and a reaction force device 400 that provides a reaction force torque for a steering wheel SW operated by a driver of vehicle VH. Herein, as is easily understood from FIG. 1, steering wheel SW and front wheels FW are not mechanically coupled to each other, whereby electric power steering system 100 constitutes a steer-by-wire system. Note that electric power steering system 100 is not limited to the steer-by-wire system and may be a well-known steering system in which steering wheel SW and front wheels FW are mechanically coupled to each other.

Steering device 200 has an electric motor 220 that produces a steering force for steering front wheels FW, a steering control device 240 that controls driving of electric motor 220, a turning mechanism 260, and a turning angle sensor 280 that detects an actual turning angle of front wheels FW.

Electric motor 220 is an AC motor including windings of a plurality of phases, such as a three-phase brushless motor including a U-phase coil, a V-phase coil, and a W-phase coil, and has a rotation angle sensor 222 that detects a rotation angle of an output shaft. Herein, an encoder, a resolver, or the like, for example, can be used as rotation angle sensor 222. Steering control device 240 includes a micro-control unit (MCU) having a processor, a non-volatile memory, a volatile memory, an input and output circuit, a communication circuit, and the like built therein, and controls driving of electric motor 220 in accordance with an application program stored in the non-volatile memory.

Turning mechanism 260 is a well-known mechanism that converts rotation motion of the output shaft of electric motor 220 into linear motion of a steering rod 262, and a rack and a pinion are used in the present embodiment. A rotational driving force of electric motor 220 is transferred to a pinion shaft 266 via a decelerator 264. On the other hand, steering rod 262 has a rack 270 that always engages with a pinion 268 provided on pinion shaft 266. When pinion 268 rotates, steering rod 262 horizontally moves in the right or left direction of vehicle VH through rack 270 that engages with pinion 268, thereby changing turning angles of front wheels FW. Note that turning mechanism 260 is not limited to a rack and a pinion, and may be a mechanism using a ball screw, for example.

Steering device 200 converts rotation motion of electric motor 220 into linear motion of steering rod 262 through decelerator 264, pinion shaft 266, pinion 268, and rack 270, thereby steering front wheels FW to the right or left via a steering knuckle coupled to a leading end of steering rod 262.

Reaction force device 400 has a steering shaft 420 that rotates integrally with steering wheel SW, an electric motor 440 that produces a reaction force torque, a reaction force control device 460 that controls driving of electric motor 440, and a steering angle sensor 480 that detects a steering angle, which is an operation angle of steering wheel SW. Herein, electric motor 440 is a three-phase brushless motor similar to electric motor 220 of steering device 200, and includes a rotation angle sensor 442 that detects a rotation angle of an output shaft. Reaction force control device 460 includes a MCU having a processor, a non-volatile memory, a volatile memory, an input and output circuit, a communication circuit, and the like built therein similarly to steering control device 240 of steering device 200, and controls driving of electric motor 440 in accordance with an application program stored in the non-volatile memory.

Steering control device 240 of steering device 200 compares the actual turning angle of front wheels FW detected by turning angle sensor 280 and the steering angle of steering wheel SW detected by steering angle sensor 480 of reaction force device 400, and controls driving of electric motor 220 of steering device 200. Reaction force control device 460 of reaction force device 400 obtains a target reaction force torque based on the steering angle of steering wheel SW detected by steering angle sensor 480, a vehicle speed, and the like, and controls driving of electric motor 440 in accordance with this target reaction force torque.

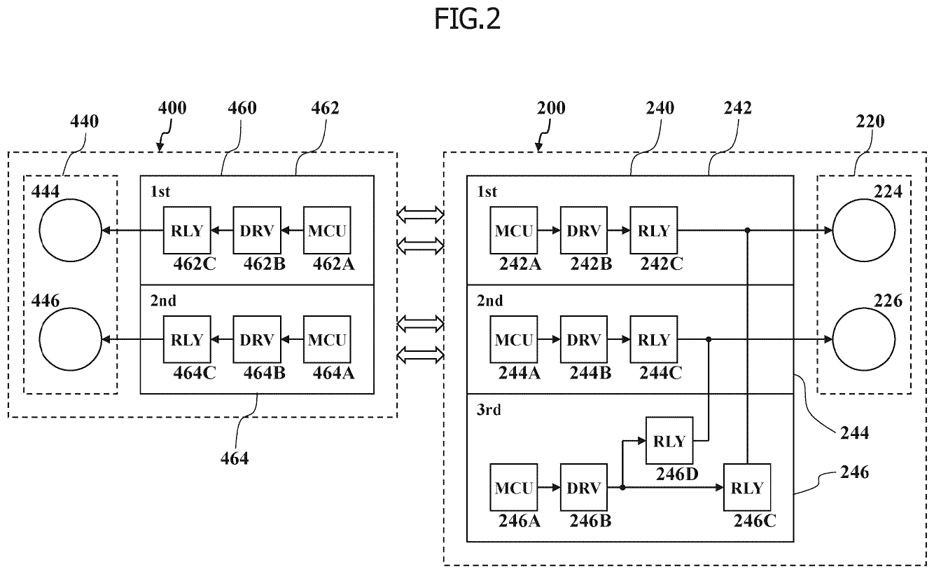

FIG. 2 shows an example of a control system of electric power steering system 100.

In the present embodiment, in order to prevent a sudden loss of assistance due to a failure while considering the applicability to Level 5 autonomous driving, electric motor 220 of steering device 200 and electric motor 440 of reaction force device 400 each have a duplex redundant configuration, and their control systems each have a duplex or triplex redundant configuration.

Electric motor 220 of steering device 200 has a first motor 224 including windings formed by a U-phase coil, a V-phase coil, and a W-phase coil and a second motor 226 including windings formed by a U-phase coil, a V-phase coil, and a W-phase coil stored in the same casing. In steering device 200, first motor 224 and second motor 226 operate in parallel to steer front wheels FW of vehicle VH to the right or left.

Steering control device 240 has a first control device 242 capable of controlling driving of first motor 224, a second control device 244 capable of controlling driving of second motor 226, and a third control device 246 capable of selectively controlling driving of first motor 224 or second motor 226. Therefore, first control device 242 is connected to first motor 224, second control device 244 is connected to second motor 226, and third control device 246 is connected to each of first motor 224 and second motor 226. Herein, third control device 246 provides a backup function of, when a failure occurs in either first control device 242 or second control device 244, controlling driving of first motor 224 or second motor 226 in place of them. Note that first control device 242 and second control device 244 are taken as an example of a first drive system, and third control device 246 is taken as an example of a second drive system.

First control device 242 has a MCU 242A, a drive circuit 242B, and a motor relay 242C formed by semiconductor switching elements. Second control device 244 has a MCU 244A, a drive circuit 244B, and a motor relay 244C formed by semiconductor switching elements. Third control device 246 has a MCU 246A, a drive circuit 246B, and a first motor relay 246C and a second motor relay 246D each being formed by semiconductor switching elements. Herein, at least MCUs 242A and 244A among MCU 242A of first control device 242, MCU 244A of second control device 244, and MCU 246A of third control device 246 may each be a multi-core processor. If a dual-core processor is adopted as the multi-core processor, control of driving of electric motor 220 can be performed continuously by the second processor core as a backup system even if a failure occurs in the first processor core as a main system. Note that MCU 242A, 244A, and 246A are electronically controlled devices each having a processor, a non-volatile memory, a volatile memory, an input and output circuit, and a communication circuit built therein, and can also be called a microcomputer, microcontroller, control unit, controller, or the like. MCU 242A of first control device 242 and MCU 244A of second control device 244 are taken as an example of a first micro-control unit, and MCU 246A of third control device 246 is taken as an example of a second micro-control unit.

MCU 242A of first control device 242 outputs, to drive circuit 242B, a control signal for controlling an AC current to be supplied to first motor 224. Drive circuit 242B of first control device 242 includes a pre-driver and an inverter, and supplies the AC current to first motor 224 via motor relay 242C. Herein, the inverter is a bridge circuit configured by combining a plurality of semiconductor switching elements as appropriate. Each of the semiconductor switching elements operates in response to an output signal of the pre-driver to convert a DC current supplied from a DC power supply such as a battery, not shown, into an AC current (the same applies hereinafter). Turning motor relay 242C of first control device 242 ON and OFF is controlled by MCU 242A, whereby connection and disconnection between drive circuit 242B and first motor 224 are selectively switched.

MCU 244A of second control device 244 outputs, to drive circuit 244B, a control signal for controlling an AC current to be supplied to second motor 226. Drive circuit 244B of second control device 244 includes a pre-driver and an inverter, and supplies the AC current to second motor 226 via motor relay 244C. Turning motor relay 244C of second control device 244 ON and OFF is controlled by MCU 244A, whereby connection and disconnection between drive circuit 244B and second motor 226 are selectively switched.

MCU 246A of third control device 246 outputs, to drive circuit 246B, a control signal for controlling an AC current to be supplied to either first motor 224 or second motor 226. Drive circuit 246B of third control device 246 includes a pre-driver and an inverter, and supplies the AC current to first motor 224 via first motor relay 246C or supplies the AC current to second motor 226 via second motor relay 246D. Turning first motor relay 246C of third control device 246 ON and OFF is controlled by MCU 246A, whereby connection and disconnection between drive circuit 246B and first motor 224 are selectively switched. Turning second motor relay 246D of third control device 246 ON and OFF is controlled by MCU 246A, whereby connection and disconnection between drive circuit 246B and second motor 226 are selectively switched.

MCU 242A of first control device 242, MCU 244A of second control device 244, and MCU 246A of third control device 246 execute failure diagnoses of drive circuits 242B, 244B, and 246B as well as motor relays 242C, 244C, 246C, and 246D, respectively, when activated by being powered ON.

When a failure occurs in drive circuit 242B of first control device 242, MCU 242A of first control device 242 turns OFF motor relay 242C to disconnect drive circuit 242B and first motor 224, and notifies third control device 246 of the occurrence of the failure. MCU 246A of third control device 246 notified by first control device 242 of the occurrence of the failure turns ON first motor relay 246C to connect drive circuit 246B and first motor 224. Consequently, when a failure occurs in first control device 242, third control device 246 can supply an AC current to first motor 224 to control driving thereof in place of first control device 242.

When a failure occurs in drive circuit 244B of second control device 244, MCU 244A of second control device 244 turns OFF motor relay 244C to disconnect drive circuit 244B and second motor 226, and notifies third control device 246 of the occurrence of the failure. MCU 246A of third control device 246 notified by second control device 244 of the occurrence of the failure turns ON second motor relay 246D to connect drive circuit 246B and second motor 226. Consequently, when a failure occurs in second control device 244, third control device 246 can supply an AC current to second motor 226 to control driving thereof in place of second control device 244.

When a failure occurs in drive circuit 246B of third control device 246, MCU 246A of third control device 246 turns OFF each of first motor relay 246C and second motor relay 246D to disconnect drive circuit 246B from first motor 224 and second motor 226, and notifies first control device 242 and second control device 244 of the occurrence of the failure. Consequently, MCU 242A of first control device 242 and MCU 244A of second control device 244 can recognize that the failure has occurred in third control device 246.

As described above, in steering device 200, driving of first motor 224 and second motor 226 can be controlled even if a failure occurs in any one of first control device 242, second control device 244, and third control device 246, whereby steering of front wheels FW performed by steering device 200 can be continued. Even if a failure occurs in either first control device 242 or second control device 244, third control device 246 can control driving of first motor 224 or second motor 226, whereby steering of front wheels FW performed by steering device 200 can be continued. Therefore, a sudden loss of assistance or the like, for example, can be prevented in steering device 200.

Electric motor 440 of reaction force device 400 has a first motor 444 including windings formed by a U-phase coil, a V-phase coil, and a W-phase coil, and second motor 446 including windings formed by a U-phase coil, a V-phase coil, and a W-phase coil stored in the same casing. In reaction force device 400, first motor 444 and second motor 446 operate in parallel to provide a reaction force torque to steering wheel SW of vehicle VH.

Reaction force control device 460 has a first control device 462 capable of controlling driving of first motor 444, and a second control device 464 capable of controlling driving of second motor 446. Therefore, first control device 462 is connected to first motor 444, and second control device 464 is connected to second motor 446.

First control device 462 has a MCU 462A, a drive circuit 462B, and a motor relay 462C formed by semiconductor switching elements. Second control device 464 has a MCU 464A, a drive circuit 464B, and a motor relay 464C formed by semiconductor switching elements.

MCU 462A of first control device 462 outputs, to drive circuit 462B, a control signal for controlling an AC current to be supplied to first motor 444. Drive circuit 462B of first control device 462 includes a pre-driver and an inverter, and supplies an AC current to first motor 444 via motor relay 462C. Turning motor relay 462C of first control device 462 ON and OFF is controlled by MCU 462A, whereby connection and disconnection between drive circuit 462B and first motor 444 are selectively switched.

MCU 464A of second control device 464 outputs, to drive circuit 464B, a control signal for controlling an AC current to be supplied to second motor 446. Drive circuit 464B of second control device 464 includes a pre-driver and an inverter, and supplies an AC current to second motor 446 via motor relay 464C. Turning motor relay 464C of second control device 464 ON and OFF is controlled by MCU 464A, whereby connection and disconnection between drive circuit 464B and second motor 446 are selectively switched.

Note that reaction force device 400 may have a third control device in addition to first control device 462 and second control device 464 similarly to steering control device 240. The third control device can be configured to control supply of an AC current to first motor 444 when a failure occurs in first control device 462 and to control supply of an AC current to second motor 446 when a failure occurs in second control device 464.

Herein, details of steering control device 240 that controls driving of electric motor 220 of steering device 200 will be described. Only first control device 242 will be described because first control device 242 and second control device 244 are configured in the same manner and because third control device 246 has the same configuration as first control device 242 and second control device 244 except that two motor relays are provided. Consequently, by describing first control device 242, second control device 244 and third control device 246 shall be considered as having been described. Components of second control device 244 and third control device 246 are denoted by reference characters similar to the components of first control device 242. Note that reaction force control device 460 that controls driving of electric motor 440 of reaction force device 400 is similar to steering control device 240 of steering device 200, and detailed description thereof is thus omitted.

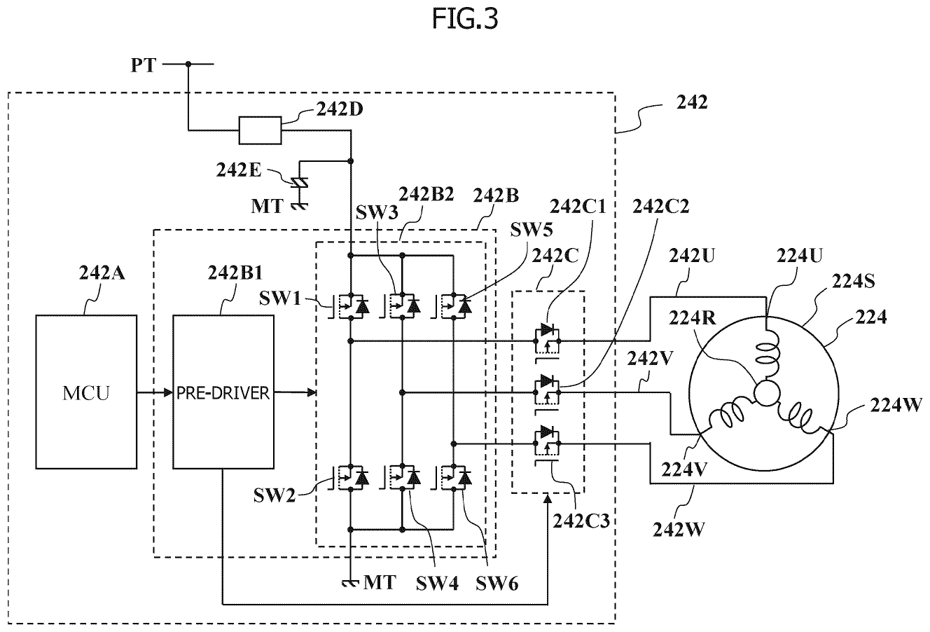

FIG. 3 shows an example of an inner structure of first motor 224 of electric motor 220 and first control device 242.

First motor 224 has a substantially cylindrical stator 224S in which a U-phase coil 224U, a V-phase coil 224V, and a W-phase coil 224W are star-connected and wound, and has a rotor 224R arranged to be freely rotatable on the inner periphery of stator 224S. Rotor 224R has a rotational drive shaft (not shown) protruding from an axial end of stator 224S to the outside, and an input shaft of decelerator 264 of steering device 200 is coupled to a protruding part of the rotational drive shaft.

First control device 242 includes a power supply relay 242D that selectively connects and disconnects a positive terminal PT of a DC power supply such as a battery and drive circuit 242B, in addition to MCU 242A, drive circuit 242B, and motor relay 242C described above. Drive circuit 242B has a pre-driver 242B1 and an inverter 242B2. Inverter 242B2 is a three-phase bridge circuit configured by connecting semiconductor switching elements SW1 to SW6 such as P-channel metal oxide semiconductor field effect transistors (MOSFETs) having a parasitic diode (reflux diode) as appropriate. Herein, semiconductor switching elements SW1 to SW6 are not limited to the P-channel MOSFETs and may be N-channel MOSFETs, insulated gate bipolar transistors (IGPTs), or the like (the same applies hereinafter). Note that inverter 242B2 of first control device 242 is taken as an example of a first inverter.

Specifically, inverter 242B2 has a U-phase arm in which semiconductor switching elements SW1 and SW2 are connected in series, a V-phase arm in which semiconductor switching elements SW3 and SW4 are connected in series, and a W-phase arm in which semiconductor switching elements SW5 and SW6 are connected in series.

In the U-phase arm, the source of semiconductor switching element SW1 on an upper stage is connected to positive terminal PT of the DC power supply via power supply relay 242D, the drain of semiconductor switching element SW1 on the upper stage is connected to the source of semiconductor switching element SW2 on a lower stage, and the drain of semiconductor switching element SW2 on the lower stage is connected to negative terminal MT of the DC power supply. An electric path positioned between semiconductor switching element SW1 on the upper stage and semiconductor switching element SW2 on the lower stage is connected to U-phase coil 224U of first motor 224 via a U-phase drive line 242U.

In the V-phase arm, the source of semiconductor switching element SW3 on the upper stage is connected to positive terminal PT of the DC power supply via power supply relay 242D, the drain of semiconductor switching element SW3 on the upper stage is connected to the source of semiconductor switching element SW4 on the lower stage, and the drain of semiconductor switching element SW4 on the lower stage is connected to negative terminal MT of the DC power supply. An electric path positioned between semiconductor switching element SW3 on the upper stage and semiconductor switching element SW4 on the lower stage is connected to V-phase coil 224V of first motor 224 via a V-phase drive line 242V.

In the W-phase arm, the source of semiconductor switching element SW5 on the upper stage is connected to positive terminal PT of the DC power supply via power supply relay 242D, the drain of semiconductor switching element SW5 on the upper stage is connected to the source of semiconductor switching element SW6 on the lower stage, and the drain of semiconductor switching element SW6 on the lower stage is connected to negative terminal MT of the DC power supply. An electric path positioned between semiconductor switching element SW5 on the upper stage and semiconductor switching element SW6 on the lower stage is connected to W-phase coil 224W of first motor 224 via a W-phase drive line 242W.

Motor relay 242C, which is arranged in the middle of U-phase drive line 242U, V-phase drive line 242V, and W-phase drive line 242W, selectively connects or disconnects U-phase drive line 242U, V-phase drive line 242V, and W-phase drive line 242W that connect inverter 242B2 and first motor 224. Motor relay 242C has a U-phase relay 242C1 that selectively connects or disconnects U-phase drive line 242U, a V-phase relay 242C2 that selectively connects or disconnects V-phase drive line 242V, and a W-phase relay 242C3 that selectively connects or disconnects W-phase drive line 242W, as is clear from FIG. 3. U-phase relay 242C1, V-phase relay 242C2, and W-phase relay 242C3 are each formed by a P-channel MOSFET having a parasitic diode, and they operate in the same state in response to a command from MCU 242A.

A capacitor 242E having a predetermined electric capacity is arranged on a branch path that branches off from the electric path connecting inverter 242B2 and power supply relay 242D and that is connected to negative terminal MT of the DC power supply. This capacitor 242E is charged while power supply relay 242D is operating, and is used for diagnosing whether an open (disconnection) failure occurs in inverter 242B2 and motor relay 242C when first control device 242 is activated, details of which will be described later.

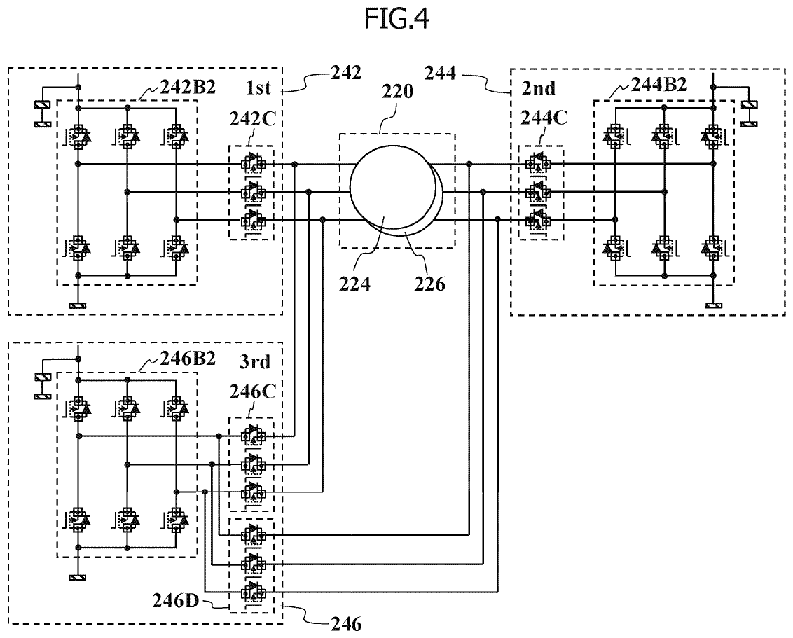

First control device 242, second control device 244, and third control device 246 configured as described above are connected to electric motor 220 to control driving thereof as shown in FIG. 4. In other words, inverter 242B2 of first control device 242 is connected to U-phase coil 224U, V-phase coil 224V, and W-phase coil 224W of first motor 224 of electric motor 220 via motor relay 242C. Inverter 244B2 of second control device 244 is connected to a U-phase coil 226U, a V-phase coil 226V, and a W-phase coil 226W of second motor 226 of electric motor 220 via motor relay 244C. Inverter 246B2 of third control device 246 is connected to U-phase drive line 242U, V-phase drive line 242V, and W-phase drive line 242W that connect first control device 242 and first motor 224 of electric motor 220 via first motor relay 246C. Inverter 246B2 of third control device 246 is connected to a U-phase drive line 244U, a V-phase drive line 244V, and a W-phase drive line 244W that connect second control device 244 and second motor 226 of electric motor 220 via second motor relay 246D. In short, third control device 246 is connected so as to continuously control driving of first motor 224 or second motor 226 of electric motor 220 when a failure occurs in either first control device 242 or second control device 244. Note that inverter 244B2 of second control device 244 is taken as an example of the first inverter, and inverter 246B2 of third control device 246 is taken as an example of the second inverter.

Herein, a method for diagnosing inverter 242B2 and motor relay 242C, which is executed in first control device 242 following activation at powering ON, will be described. Note that although the method for diagnosing first control device 242 will be described below, each of inverters 244B2 and 246B2 as well as motor relays 244C, 246C, and 246D can also be diagnosed in second control device 244 and third control device 246 based on similar principles.

When first control device 242 is activated, a diagnosis is executed in a state in which power supply relay 242D is disconnected so as to prevent the current of the DC power supply from flowing downstream due to a short failure in inverter 242B2. At this time, in order to use the inter-terminal voltage of first motor 224 as a diagnosis parameter, motor relay 242C is operated to connect inverter 242B2 and first motor 224. Note that the diagnosis of inverter 242B2 is performed using charges accumulated in capacitor 242E because the current is not supplied from the DC power supply.

At first, MCU 242A operates semiconductor switching elements SW2, SW4, and SW6 on the lower stage of inverter 242B2 via pre-driver 242B1 only for a predetermined time. Then, MCU 242A compares an inter-terminal voltage V0 of capacitor 242E and an inter-terminal voltage V1 of first motor 224 for each of the U-phase arm, the V-phase arm, and the W-phase arm, and diagnoses whether a short failure in semiconductor switching elements SW1, SW3, and SW5 has occurred on the upper stage of inverter 242B2.

If semiconductor switching elements SW1, SW3, and SW5 on the upper stage of inverter 242B2 are normal, the current supplied from capacitor 242E flows through the parasitic diodes of semiconductor switching elements SW1, SW3, and SW5 on the upper stage. At this time, a voltage drop is caused by the parasitic diodes of semiconductor switching elements SW1, SW3, and SW5 on the upper stage. When an equivalence of this voltage drop is represented by Vf, a correlation that V0−V1=2*Vf holds. Consequently, MCU 242A can diagnose that semiconductor switching elements SW1, SW3, and SW5 on the upper stage are normal if V0−V1=2*Vf holds when semiconductor switching elements SW2, SW4, and SW6 on the lower stage of inverter 242B2 are operated.

On the other hand, if a short failure occurs in semiconductor switching elements SW1, SW3, and SW5 on the upper stage of inverter 242B2, the current supplied from capacitor 242E flows through semiconductor switching elements SW1, SW3, and SW5 on the upper stage, and V0−V1=Vf holds. Consequently, MCU 242A can diagnose that a short failure has occurred in semiconductor switching elements SW1, SW3, and SW5 on the upper stage if V0-−V1=Vf holds when semiconductor switching elements SW2, SW4, and SW6 on the lower stage of inverter 242B2 are operated.

Next, MCU 242A operates semiconductor switching elements SW1, SW3, and SW5 on the upper stage of inverter 242B2 via pre-driver 242B1 only for a predetermined time. Then, MCU 242A compares the inter-terminal voltage V0 of capacitor 242E and the inter-terminal voltage V1 of first motor 224 for each of the U-phase arm, the V-phase arm, and the W-phase arm, and diagnoses whether a short failure in semiconductor switching elements SW2, SW4, and SW6 has occurred on the lower stage of inverter 242B2.

If semiconductor switching elements SW2, SW4, and SW6 on the lower stage of inverter 242B2 are normal, the current supplied from capacitor 242E flows through the parasitic diode of motor relay 242C. When the equivalence of this voltage drop is represented by Vf, a correlation that V0−V1=Vf holds. Consequently, MCU 242A can diagnose that semiconductor switching elements SW2, SW4, and SW6 on the lower stage are normal if V0−V1=Vf, that is, V1=V0−Vf holds when semiconductor switching elements SW1, SW3, and SW5 on the upper stage of inverter 242B2 are operated.

On the other hand, if a short failure occurs in semiconductor switching elements SW2, SW4, and SW6 on the lower stage of inverter 242B2, the current supplied from capacitor 242E flows through semiconductor switching elements SW2, SW4, and SW6 on the lower stage, and V0=0 holds. Consequently, MCU 242A can diagnose that a short failure has occurred in semiconductor switching elements SW2, SW4, and SW6 on the lower stage if V0−V1=Vf, that is, V1=−Vf holds when semiconductor switching elements SW1, SW3, and SW5 on the upper stage of inverter 242B2 are operated.

When an open failure occurs in semiconductor switching elements SW1, SW3, and SW5 on the upper stage of inverter 242B2, V1=0 holds. Thus, MCU 242A can diagnose that an open failure has occurred in semiconductor switching elements SW1, SW3, and SW5 on the upper stage. When an open failure occurs in motor relay 242C when semiconductor switching elements SW1, SW3, and SW5 on the upper stage of inverter 242B2 are operated, V1=0 holds. Thus, MCU 242A can also diagnose whether an open failure has occurred in motor relay 242C simultaneously.

Consequently, by executing an application program that implements the principles as described above, MCU 242A can diagnose whether an open failure and a short failure in semiconductor switching elements SW1 to SW6 of inverter 242B2 occurred, as well as U-phase relay 242C1, V-phase relay 242C2, and W-phase relay 242C3 of motor relay 242C. Note that MCU 242A may be configured to first operate semiconductor switching elements SW1, SW3, and SW5 on the upper stage of inverter 242B2 to execute a failure diagnosis, and then operate semiconductor switching elements SW2, SW4, and SW6 on the lower stage of inverter 242B2 to execute a failure diagnosis.

When a failure in the inverters and motor relays in first control device 242 and third control device 246 or second control device 244 and third control device 246 is diagnosed simultaneously, a defect, which will be described below, may occur. The following description is based on execution of a failure diagnosis of the inverters of first control device 242 and third control device 246, and it is supposed that an open failure has occurred in any of semiconductor switching elements SW1, SW3, and SW5 on the upper stage of inverter 242B2 of first control device 242.

When semiconductor switching elements SW1, SW3, and SW5 on the upper stage are turned on simultaneously in first control device 242 and third control device 246, the current supplied from capacitor 242E does not flow because an open failure has occurred in semiconductor switching elements SW1, SW3, and SW5 on the upper stage in first control device 242. Therefore, in first control device 242, the inter-terminal voltage V1 of first motor 224 of electric motor 220 becomes 0. However, the current flows through the parasitic diodes of semiconductor switching elements SW2, SW4, and SW6 on the lower stage as well as semiconductor switching elements SW1, SW3, and SW5 on the upper stage because a failure has not occurred in inverter 246B2 in third control device 246, whereby the inter-terminal voltage of first motor 224 of electric motor 220 becomes Vf. Consequently, in the failure diagnosis of first control device 242, the inter-terminal voltage of first motor 224 of electric motor 220 becomes Vf because of third control device 246, and the correlation that V0−V1=Vf holds, so that semiconductor switching elements SW1, SW3, and SW5 are erroneously diagnosed as being normal.

Therefore, in the present embodiment, a failure diagnosis of one of first control device 242 and third control device 246 is executed when a current is not supplied to semiconductor switching elements SW1 to SW6 of inverters 242B2 and 246B2 of the other of first control device 242 and third control device 246. In short, MCU 242A of first control device 242 executes a failure diagnosis when a current is not supplied to semiconductor switching elements SW1 to SW6 of inverter 246B2 in third control device 246. On the other hand, MCU 246A of third control device 246 executes a failure diagnosis when a current is not supplied to semiconductor switching elements SW1 to SW6 of inverter 242B2 in first control device 242. Hereinafter, control that implements such characteristics will be described in detail. Note that although first control device 242 and third control device 246 that control driving of first motor 224 of electric motor 220 will be described hereinafter, the processing can also obviously be applied to second control device 244 and third control device 246 that control driving of second motor 226 of electric motor 220.

### First Embodiment

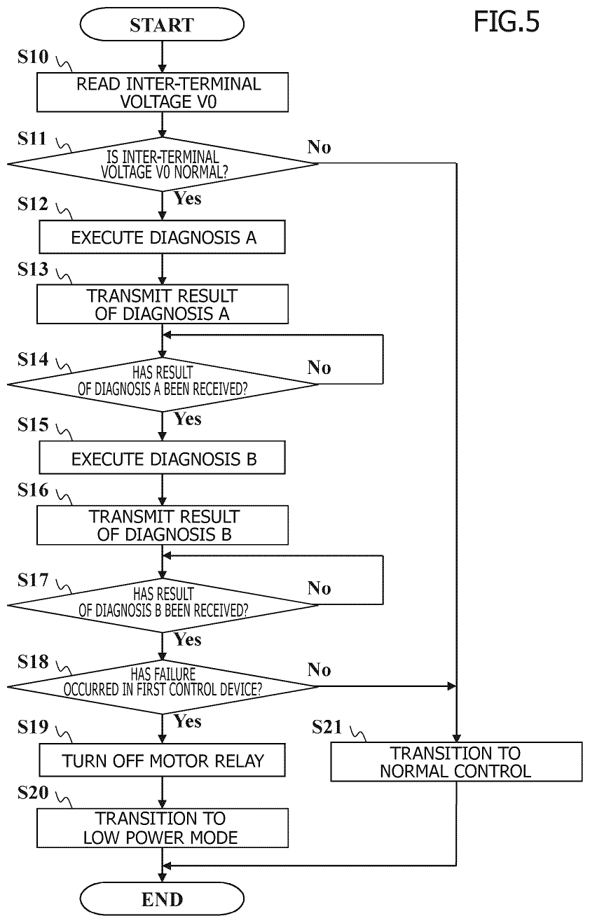

FIG. 5 shows an example of first diagnosis processing to be executed by MCU 242A of first control device 242 following activation of first control device 242. Note that the first diagnosis processing is executed in accordance with an application program stored in the non-volatile memory of MCU 242A (the same applies hereinafter).

In step 10 (abbreviated to “S10” in FIG. 5; the same applies hereinafter), MCU 242A reads the inter-terminal voltage V0 of capacitor 242E from a voltage sensor, for example.

In step 11, MCU 242A determines whether the inter-terminal voltage V0 of capacitor 242E is normal, that is, whether a diagnosis of inverter 242B2 and motor relay 242C can be executed with charges accumulated in capacitor 242E. When determining that the inter-terminal voltage V0 is normal (Yes), MCU 242A advances the process to step 12. On the other hand, when determining that the inter-terminal voltage V0 is not normal, that is, the diagnosis of inverter 242B2 and motor relay 242C cannot be executed with charges accumulated in capacitor 242E (No), MCU 242A advances the process to step 21.

In step 12, MCU 242A operates semiconductor switching elements SW2, SW4, and SW6 on the lower stage of inverter 242B2 via pre-driver 242B1 for a predetermined time, and executes a “diagnosis A” of diagnosing whether a short failure in semiconductor switching elements SW1, SW3, and SW5 occurred on the upper stage. Note that this diagnosis processing has already been described in detail, and details thereof will thus not be further described below. The previous description should be referred to, if necessary.

In step 13, MCU 242A transmits a diagnosis result of diagnosis A to MCU 246A of third control device 246 (notifies MCU 246A). Consequently, MCU 246A of third control device 246 having received the diagnosis result of diagnosis A from first control device 242 can recognize that diagnosis A in first control device 242 has been completed.

In step 14, MCU 242A determines whether the diagnosis result of diagnosis A has been received from third control device 246, that is, whether diagnosis A has been completed in third control device 246. When determining that the diagnosis result of diagnosis A has been received (Yes), MCU 242A advances the process to step 15. On the other hand, when determining that the diagnosis result of diagnosis A has not been received (No), MCU 242A repeatedly executes the determination processing in step 14 again. In short, MCU 242A waits in step 14 until diagnosis A is completed in third control device 246.

In step 15, MCU 242A operates semiconductor switching elements SW1, SW3, and SW5 on the upper stage of inverter 242B2 via pre-driver 242B1 for a predetermined time, and executes a “diagnosis B” of diagnosing whether a short failure in semiconductor switching elements SW2, SW4, and SW6 has occurred on the lower stage as well as motor relay 242C, and whether an open failure in semiconductor switching elements SW2, SW4, and SW6 has occurred on the lower stage. Note that this diagnosis processing has already been described in detail, and details thereof will thus not be further described below. The previous description should be referred to, if necessary.

In step 16, MCU 242A transmits a diagnosis result of diagnosis B to MCU 246A of third control device 246. Consequently, MCU 246A of third control device 246 having received the diagnosis result of diagnosis B from first control device 242 can recognize that diagnosis B in first control device 242 has been completed.

In step 17, MCU 242A determines whether the diagnosis result of diagnosis B has been received from third control device 246, that is, whether diagnosis B has been completed in third control device 246. When determining that the diagnosis result of diagnosis B has been received (YES), MCU 242A advances the process to step 18. On the other hand, when determining that the diagnosis result of diagnosis B has not been received (NO), MCU 242A repeatedly executes the determination processing in step 17 again. In short, MCU 242A waits at step 17 until diagnosis B is completed in third control device 246.

In step 18, MCU 242A determines whether a failure has occurred in at least one of inverter 242B2 and motor relay 242C of first control device 242 in accordance with the diagnosis results of diagnosis A and diagnosis B in first control device 242. When determining that a failure has occurred in at least one of inverter 242B2 and motor relay 242C (YES), MCU 242A advances the process to step 19. On the other hand, when determining that a failure has occurred in neither inverter 242B2 nor motor relay 242C (NO), MCU 242A advances the process to step 21.

In step 19, MCU 242A turns off motor relay 242C as a preparation for bringing over control on driving of first motor 224 to third control device 246 because a failure has occurred in first control device 242. Consequently, drive circuit 242B and first motor 224 are disconnected in first control device 242, whereby first control device 242 can no longer control driving of first motor 224.

In step 20, MCU 242A causes the operation mode to transition to a low power mode so as to reduce the DC power supply consumption because first control device 242 does not need to control driving of first motor 224 any longer. Herein, in the low power mode, it is considered to operate only a wake-up function to be activated in response to an activation signal received from the outside (the same applies hereinafter). Note that MCU 242A may stop first control device 242 instead of causing the operation mode to transition to the low power mode (the same applies hereinafter).

In step 21, MCU 242A transitions to normal control of controlling driving of first motor 224 of electric motor 220 because the inter-terminal voltage V0 of capacitor 242E is not normal, and thus, the diagnosis cannot be executed or because a failure has not occurred in first control device 242. Note that the normal control includes a fail-safe procedure assumed to be performed in first control device 242, and the like (the same applies hereinafter).

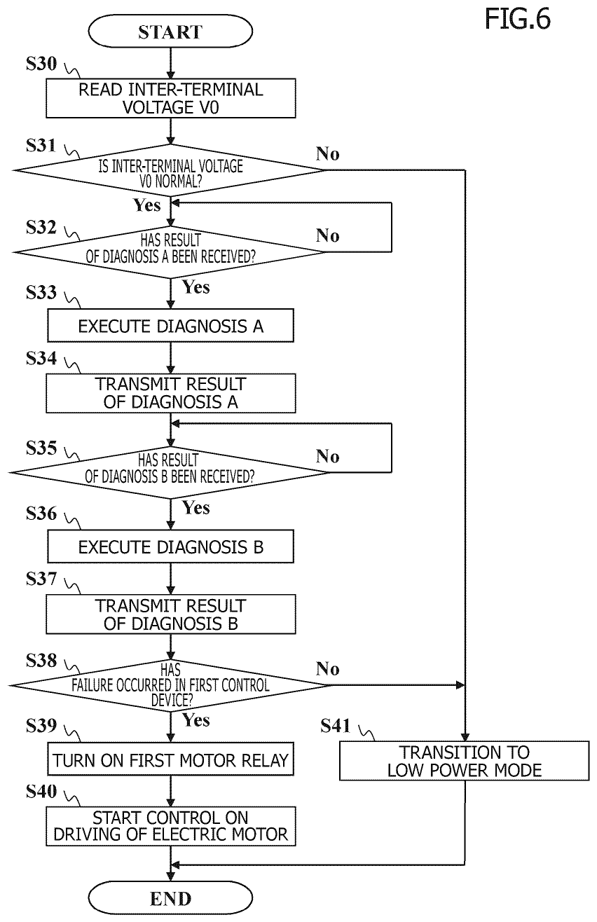

FIG. 6 shows an example of first diagnosis processing to be executed by MCU 246A of third control device 246 following activation of third control device 246. Note that the first diagnosis processing is executed in accordance with an application program stored in the non-volatile memory of MCU 246A. Processing similar to the first diagnosis processing in first control device 242 will be described briefly to avoid repeated description (the same applies hereinafter). The previous description should be referred to, if necessary.

In step 30, MCU 246A reads the inter-terminal voltage V0 of a capacitor 246E.

In step 31, MCU 246A determines whether the inter-terminal voltage V0 of capacitor 246E is normal. When determining that the inter-terminal voltage V0 is normal (YES), MCU 246A advances the process to step 32. On the other hand, when determining that the inter-terminal voltage V0 is not normal (NO), MCU 246A advances the process to step 41.

In step 32, MCU 246A determines whether the diagnosis result of diagnosis A has been received from first control device 242, that is, whether diagnosis A has been completed in first control device 242. When determining that the diagnosis result of diagnosis A has been received (YES), MCU 246A advances the process to step 33. On the other hand, when determining that the diagnosis result of diagnosis A has not been received (NO), MCU 246A repeatedly executes the determination processing in step 32 again. In short, MCU 246A waits at step 32 until diagnosis A is completed in first control device 242.

In step 33, MCU 246A executes diagnosis A.

In step 34, MCU 246A transmits the diagnosis result of diagnosis A to MCU 242A of first control device 242. Consequently, MCU 242A of first control device 242 having received the diagnosis result of diagnosis A from third control device 246 can recognize that diagnosis A in third control device 246 has been completed.

In step 35, MCU 246A determines whether the diagnosis result of diagnosis B has been received from first control device 242, that is, whether diagnosis B has been completed in first control device 242. When determining that the diagnosis result of diagnosis B has been received (YES), MCU 246A advances the process to step 36. On the other hand, when determining that the diagnosis result of diagnosis B has not been received (NO), MCU 246A repeatedly executes the determination processing in step 35 again. In short, MCU 246A waits in step 35 until diagnosis B is completed in first control device 242.

In step 36, MCU 246A executes diagnosis B.

In step 37, MCU 246A transmits the diagnosis result of diagnosis B to MCU 242A of first control device 242. Consequently, MCU 242A of first control device 242 having received the diagnosis result of diagnosis B from third control device 246 can recognize that diagnosis B in third control device 246 has been completed.

In step 38, MCU 246A determines whether a failure has occurred in at least one of inverter 242B2 and motor relay 242C of first control device 242 in accordance with the diagnosis results of diagnosis A and diagnosis B received from first control device 242. When determining that a failure has occurred in first control device 242 (YES), MCU 246A advances the process to step 39. On the other hand, when determining that a failure has not occurred in first control device 242 (NO), MCU 246A advances the process to step 41.

In step 39, MCU 246A turns on first motor relay 246C so as to undertake control on driving of first motor 224 of electric motor 220 from first control device 242 because a failure has occurred in first control device 242. Consequently, drive circuit 246B of third control device 246 and first motor 224 are connected to each other because of turning on of first motor relay 246C, which enables third control device 246 to control driving of first motor 224.

In step 40, MCU 246A starts control for driving of first motor 224 of electric motor 220. In short, third control device 246 undertakes control for driving of first motor 224 so as to back up the inability to control driving of first motor 224 due to the failure in first control device 242.

In step 41, MCU 246A causes the operation mode to transition to the low power mode so as to reduce the DC power supply consumption because the inter-terminal voltage V0 of capacitor 242E is not normal, and thus, the diagnosis cannot be executed or because a failure has not occurred in first control device 242. Note that MCU 246A may stop third control device 246 instead of causing the operation mode to transition to the low power mode (the same applies hereinafter).

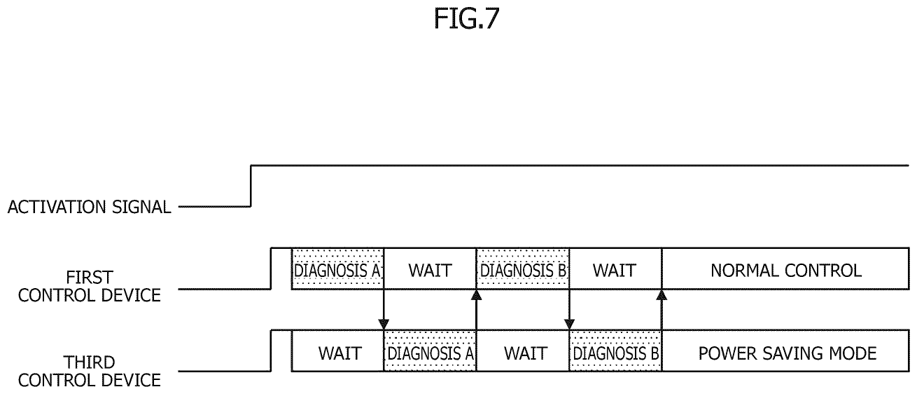

According to the first diagnosis processing, after an activation signal is on and a diagnosis of hardware and the like is completed as shown in FIG. 7, MCU 242A of first control device 242 executes diagnoses A and B prior to the failure diagnoses to be executed by MCU 246A of third control device 246. In other words, when the activation signal is on and the diagnosis of hardware and the like is completed, diagnosis A is first executed in first control device 242. Third control device 246 waits while diagnosis A is being executed in first control device 242. When diagnosis A is completed in first control device 242, diagnosis A is executed in third control device 246. First control device 242 waits while diagnosis A is being executed in third control device 246.

When diagnosis A is completed in third control device 246, diagnosis B is executed in first control device 242. Third control device 246 waits while diagnosis B is being executed in first control device 242. When diagnosis B is completed in first control device 242, diagnosis B is executed in third control device 246. First control device 242 waits while diagnosis B is being executed in third control device 246. Thereafter, when diagnosis B in third control device 246 is completed, if a failure has not occurred in first control device 242, a transition is made to the normal control in which first control device 242 controls driving of first motor 224, and third control device 246 transitions to the low power mode. On the other hand, if a failure has occurred in first control device 242, first control device 242 and first motor 224 are disconnected from each other, and third control device 246 and first motor 224 are connected to each other, whereby third control device 246 undertakes control on driving of first motor 224.

In first control device 242 and third control device 246, diagnosis A and diagnosis B are not executed simultaneously, as is easily recognized from FIG. 7. Consequently, in first control device 242 and third control device 246, semiconductor switching elements SW1 to SW6 of inverters 242B2 and 246B2 do not operate simultaneously. Therefore, AC currents are not supplied from first control device 242 and third control device 246 to first motor 224 simultaneously, which can avoid an erroneous diagnosis of whether failure has occurred in inverters 242B2 and 246B2 as well as motor relays 242C, 246C, and 246D.

### Second Embodiment

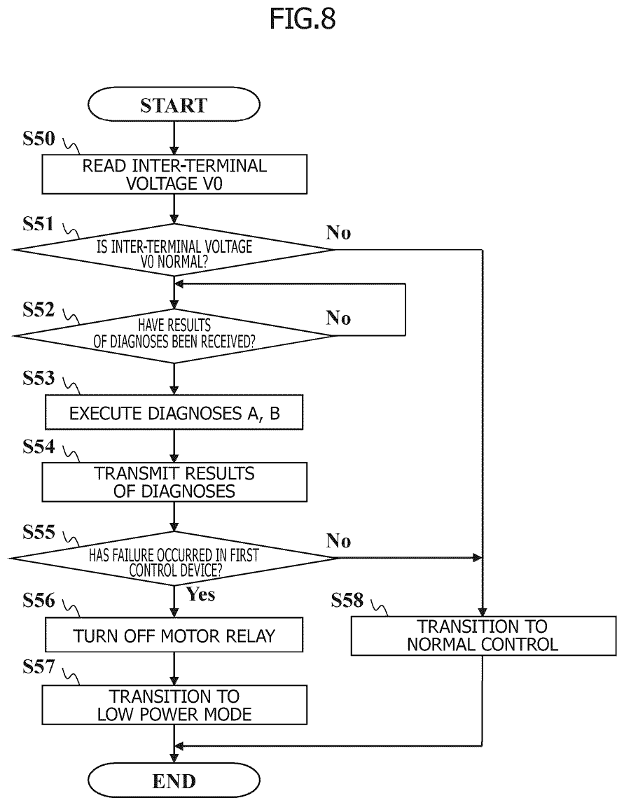

FIG. 8 shows an example of second diagnosis processing to be executed by MCU 242A of first control device 242 following activation of first control device 242.

In step 50, MCU 242A reads the inter-terminal voltage V0 of capacitor 242E.

In step 51, MCU 242A determines whether the inter-terminal voltage V0 of capacitor 242E is normal. When it is determined that the inter-terminal voltage V0 is normal (YES), MCU 242A advances the process to step 52. On the other hand, when determining that the inter-terminal voltage V0 is not normal (NO), MCU 242A advances the process to step 58.

In step 52, MCU 242A determines whether the diagnosis results of diagnoses A and B have been received from third control device 246. When determining that the diagnosis results of diagnoses A and B have been received (YES), MCU 242A advances the process to step 53. On the other hand, when determining that the diagnosis results of diagnoses A and B have not been received (NO), MCU 242A executes the determination processing in step 52 again. In short, MCU 242A waits at step 52 until the diagnosis results are received from the third control device 246.

In step 53, MCU 242A executes diagnoses A and B consecutively.

In step 54, MCU 242A transmits the diagnosis results of diagnoses A and B to MCU 246A of third control device 246. Consequently, MCU 246A of third control device 246 having received the diagnosis results can recognize that diagnoses A and B in first control device 242 have been completed.

In step 55, MCU 242A determines whether a failure has occurred in at least one of inverter 242B2 and motor relay 242C of first control device 242 in accordance with the diagnosis results of diagnoses A and B in first control device 242. When determining that a failure has occurred in first control device 242 (YES), MCU 242A advances the process to step 56. On the other hand, when determining that a failure has not occurred in first control device 242 (NO), MCU 242A advances the process to step 58.

In step 56, MCU 242A turns off motor relay 242C as a preparation for bringing over control on driving of first motor 224 to third control device 246 because a failure has occurred in first control device 242.

In step 57, MCU 242A causes the operation mode to transition to the low power mode so as to reduce the DC power supply consumption because driving of first motor 224 can no longer be controlled by first control device 242.

In step 58, MCU 242A transitions to the normal control of controlling driving of first motor 224 because diagnoses A and B cannot be performed using charges in capacitor 242E or because first control device 242 is normal.

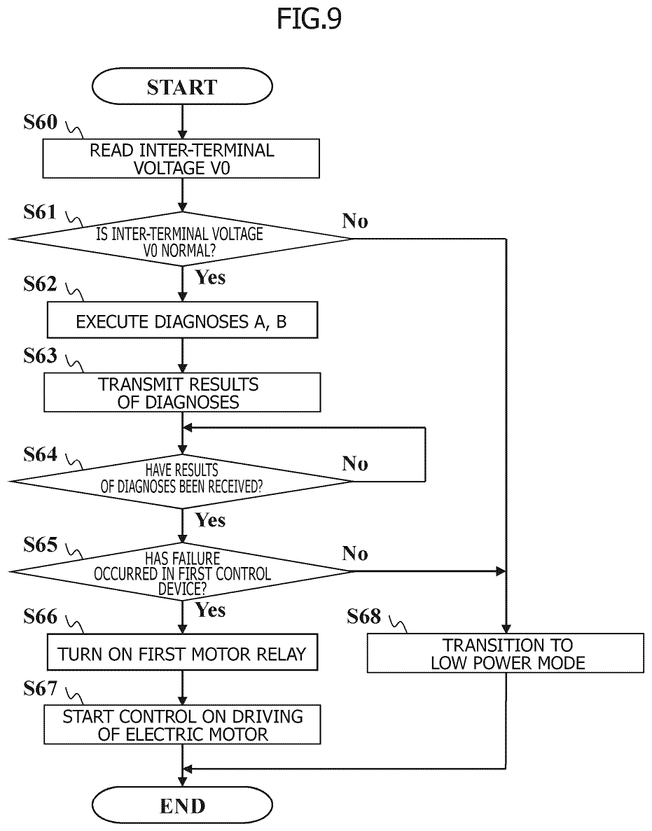

FIG. 9 shows an example of second diagnosis processing to be executed by MCU 246A of third control device 246 following activation of third control device 246.

In step 60, MCU 246A reads the inter-terminal voltage V0 of capacitor 246E.

In step 61, MCU 246A determines whether the inter-terminal voltage V0 of capacitor 246E is normal. When determining that the inter-terminal voltage V0 is normal (YES), MCU 246A advances the process to step 62. On the other hand, when determining that the inter-terminal voltage V0 is not normal (NO), MCU 246A advances the process to step 68.

In step 62, MCU 246A executes diagnoses A and B consecutively.

In step 63, MCU 246A transmits the diagnosis results of diagnoses A and B to MCU 242A of first control device 242. Consequently, MCU 242A of first control device 242 having received the diagnosis results in third control device 246 can recognize that diagnoses A and B in third control device 246 have been completed.

In step 64, MCU 246A determines whether the diagnosis results of diagnoses A and B have been received from first control device 242. When determining that the diagnosis results have been received from first control device 242 (YES), MCU 246A advances the process to step 65. On the other hand, when determining that the diagnosis results have not been received from first control device 242 (NO), MCU 246A executes the determination processing in step 64 again. In short, MCU 246A waits in step 64 until diagnoses A and B in first control device 242 have been completed.

In step 65, MCU 246A determines whether a failure has occurred in at least one of inverter 242B2 and motor relay 242C of first control device 242 in accordance with the diagnosis results of diagnoses A and B received from first control device 242. When determining that a failure has occurred in first control device 242 (YES), MCU 246A advances the process to step 66. On the other hand, when determining that a failure has not occurred in first control device 242 (NO), MCU 246A advances the process to step 68.

In step 66, MCU 246A turns on first motor relay 246C so as to undertake control on driving of first motor 224 of electric motor 220 from first control device 242 because a failure has occurred in first control device 242.

In step 67, MCU 246A starts control on driving of first motor 224 of electric motor 220.

In step 68, MCU 246A causes the operation mode to transition to the low power mode so as to reduce the DC power supply consumption because diagnoses A and B cannot be executed with charges accumulated in capacitor 246E or because a failure has not occurred in first control device 242.

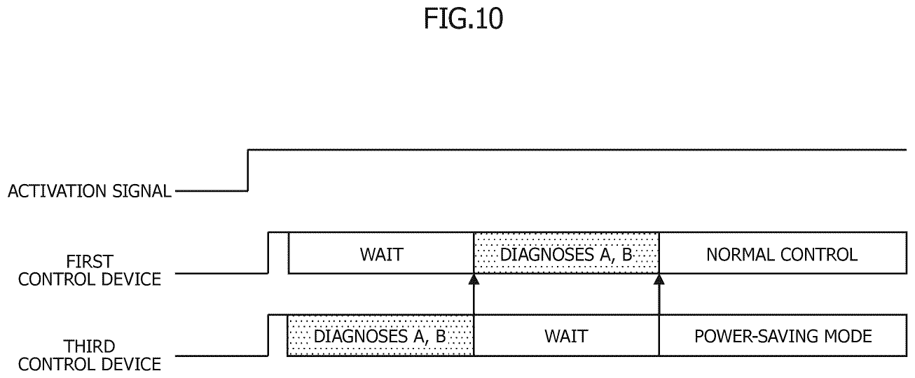

According to the second diagnosis processing, MCU 246A of third control device 246 executes diagnoses A and B consecutively prior to the failure diagnoses of inverter 242B2 to be executed by MCU 242A of first control device 242 as shown in FIG. 10, unlike the first diagnosis processing. In other words, in the second diagnosis processing, diagnoses A and B in third control device 246 are first executed consecutively, and meanwhile, first control device 242 waits, unlike the first diagnosis processing. When diagnoses A and B in third control device 246 are completed, diagnoses A and B in first control device 242 are then executed consecutively, and meanwhile, third control device 246 waits. Consequently, messages to be exchanged between first control device 242 and third control device 246 decrease, whereby an execution time can be shortened accordingly.

In first control device 242 and third control device 246, diagnosis A and diagnosis B are not executed simultaneously as is easily recognized from FIG. 10. Consequently, in first control device 242 and third control device 246, semiconductor switching elements SW1 to SW6 of inverters 242B2 and 246B2 do not operate simultaneously. Therefore, AC currents are not supplied from first control device 242 and third control device 246 to first motor 224 simultaneously, which can avoid an erroneous diagnosis of whether a failure has occurred in inverters 242B2 and 246B2, as well as is motor relays 242C, 246C, and 246D. Note that other actions and effects are similar to those of the first embodiment, and description thereof will thus be omitted to avoid repeated description. The description of the first embodiment should be referred to, if necessary.

### Third Embodiment

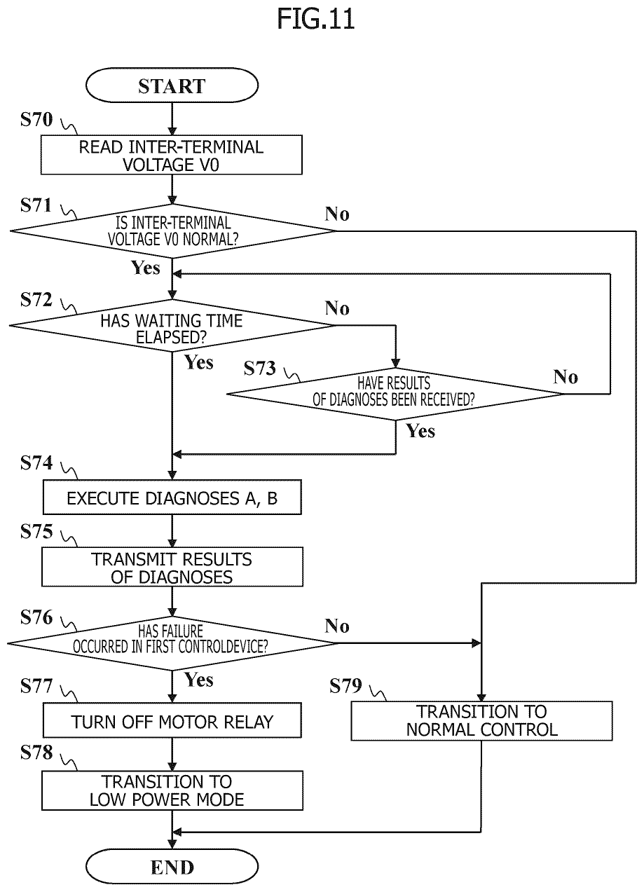

FIG. 11 shows an example of third diagnosis processing to be executed by MCU 242A of first control device 242 following activation of first control device 242.

In step 70, MCU 242A reads the inter-terminal voltage V0 of capacitor 242E.

In step 71, MCU 242A determines whether the inter-terminal voltage V0 of capacitor 242E is normal. When determining that the inter-terminal voltage V0 is normal (YES), MCU 242A advances the process to step 72. On the other hand, when determining that the inter-terminal voltage V0 is not normal (NO), MCU 242A advances the process to step 79.

In step 72, MCU 242A determines whether a predetermined waiting time has elapsed after the start of the third diagnosis processing utilizing a timer function, for example.

Herein, the predetermined waiting time is a maximum time required to complete diagnoses A and B in third control device 246 and can be set as appropriate in consideration of a processing capability, a message transmission and reception capability, and the like of third control device 246, for example. When determining that the predetermined waiting time has elapsed (YES), MCU 242A advances the process to step 74. On the other hand, when determining that the predetermined waiting time has not elapsed (NO), MCU 242A advances the process to step 73.

In step 73, MCU 242A determines whether the diagnosis results of diagnoses A and B have been received from third control device 246. When determining that the diagnosis results have been received from third control device 246 (YES), MCU 242A advances the process to step 74. On the other hand, when determining that the diagnosis results have not been received from third control device 246 (NO), MCU 242A returns the process to step 72.

In step 74, MCU 242A executes diagnoses A and B consecutively.

In step 75, MCU 242A transmits the diagnosis results of diagnoses A and B to MCU 246A of third control device 246.

In step 76, MCU 242A determines whether a failure has occurred in at least one of inverter 242B2 and motor relay 242C of first control device 242 in accordance with the diagnosis results of diagnoses A and B in first control device 242. When determining that a failure has occurred in first control device 242 (YES), MCU 242A advances the process to step 77. On the other hand, when determining that a failure has not occurred in first control device 242 (NO), MCU 242A advances the process to step 79.

In step 77, MCU 242A turns off motor relay 242C as a preparation for bringing over control on driving of first motor 224 to third control device 246 because a failure has occurred in first control device 242.

In step 78, MCU 242A causes the operation mode to transition to the low power mode so as to reduce the DC power supply consumption because first control device 242 cannot control driving of first motor 224.

In step 79, MCU 242A transitions to the normal control of controlling driving of first motor 224 of electric motor 220 because diagnoses A and B cannot be executed with charges accumulated in capacitor 242E or because first control device 242 is normal.

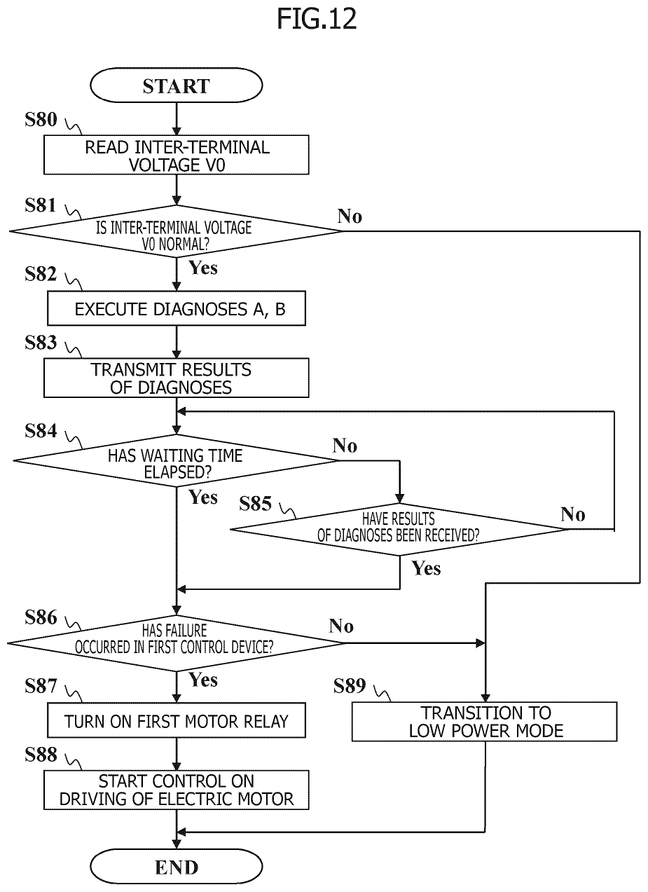

FIG. 12 shows an example of the third diagnosis processing to be executed by MCU 246A of third control device 246 following activation of third control device 246.

In step 80, MCU 246A reads the inter-terminal voltage V0 of capacitor 246E.

In step 81, MCU 246A determines whether the inter-terminal voltage V0 of capacitor 246E is normal. When determining that the inter-terminal voltage V0 is normal (YES), MCU 246A advances the process to step 82. On the other hand, when determining that the inter-terminal voltage V0 is not normal (NO), MCU 246A advances the process to step 89.

In step 82, MCU 246A executes diagnoses A and B consecutively.

In step 83, MCU 246A transmits the diagnosis results of diagnoses A and B to MCU 242A of first control device 242.

In step 84, MCU 246A determines whether a predetermined waiting time has elapsed after the start of the third diagnosis processing utilizing the timer function, for example. Herein, the predetermined waiting time is a maximum time required to complete diagnoses A and B in first control device 242 and can be set as appropriate in consideration of a processing capability, a message transmission and reception capability, and the like of first control device 242, for example. When determining that the predetermined waiting time has elapsed (YES), MCU 246A advances the process to step 86. On the other hand, when determining that the predetermined waiting time has not elapsed (NO), MCU 242A advances the process to step 85.

In step 85, MCU 246A determines whether the diagnosis results of diagnoses A and B have been received from first control device 242. When determining that the diagnosis results have been received from first control device 242 (YES), MCU 246A advances the process to step 86. On the other hand, when determining that the diagnosis results have not been received from first control device 242 (NO), MCU 246A returns the process to step 84.

In step 86, MCU 246A determines whether a failure has occurred in at least one of inverter 242B2 and motor relay 242C of first control device 242 in accordance with the diagnosis results received from first control device 242. When determining that a failure has occurred in first control device 242 (YES), MCU 246A advances the process to step 87. On the other hand, when determining that a failure has not occurred in first control device 242 (NO), MCU 246A advances the process to step 89.

In step 87, MCU 246A turns on first motor relay 246C so as to undertake control on driving of first motor 224 of electric motor 220 from first control device 242 because a failure has occurred in first control device 242.

In step 88, MCU 246A starts control on driving of first motor 224.

In step 89, MCU 246A causes the operation mode to transition to the low power mode so as to reduce the DC power supply consumption because diagnoses A and B cannot be executed with charges accumulated in capacitor 246E or because first control device 242 is normal.

According to the third diagnosis processing, first control device 242 and third control device 246 start subsequent processing such as the failure diagnoses of the inverters when being not notified of diagnosis results from the other end, even if the predetermined waiting time elapses after activation, in addition to the actions and effects of the second diagnosis processing. Therefore, even if the diagnosis results cannot be transmitted and received for some reason, execution of diagnoses A and B, determination as to whether a failure has occurred in first control device 242, or the like is performed. Consequently, the failure diagnoses of the inverters and the motor relays can be executed even in the situation in which the diagnosis results cannot be transmitted and received. Note that other actions and effects are identical to the actions and effects exerted by the second diagnosis processing, and description thereof is thus omitted for the purpose of avoiding repeated description.

Note that one of ordinary skill in the art will readily understand that a new embodiment can be created by omitting part of the technical idea of various embodiments described above, combining some of them as appropriate, or replacing part of them by a well-known technology.

To cite an example, a control target in the present proposed technology is not limited to steering device 200, and it may be reaction force device 400 or an in-vehicle well-known system. Moreover, electric motor 220 is not limited to a three-phase brushless motor but may be an electric motor including windings of any plurality of phases, or the like.

### REFERENCE SYMBOL LIST

220 Electric motor
224 First motor
226 Second motor
242 First control device (first drive system)
242A MCU (first micro-control unit)
242B2 Inverter (first inverter)
242C Motor relay (relay)
244 Second control device (first drive system)
244A MCU (first micro-control unit)
244B2 Inverter (first inverter)
244C Motor relay (relay)
246 Third control device (second drive system)
246A MCU (second micro-control unit)
246B2 Inverter (second inverter)
246C First motor relay (relay)
246D Second motor relay (relay)
SW1 to SW6 Semiconductor switching element

1. An electric motor control device comprising:
a first drive system including a first micro-control unit and a first inverter composed of a plurality of semiconductor switching elements, the first micro-control unit being configured to control the semiconductor switching elements of the first inverter and convert a DC current into an AC current to control driving of an electric motor including windings of a plurality of phases and to individually supply a current to the plurality of semiconductor switching elements of the first inverter to execute a failure diagnosis of the first inverter; and
a second drive system including a second micro-control unit and a second inverter composed of a plurality of semiconductor switching elements, the second inverter being connected to an electric path connecting the first inverter and the electric motor, the second micro-control unit being configured to, when a failure occurs in the first drive system, control the semiconductor switching elements of the second inverter and convert a DC current into an AC current to control driving of the electric motor and to individually supply a current to the plurality of semiconductor switching elements of the second inverter to execute a failure diagnosis of the second inverter, wherein
the first micro-control unit is configured to execute the failure diagnosis of the first inverter when the current is not supplied to the plurality of semiconductor switching elements of the second inverter in the second drive system, and
the second micro-control unit is configured to execute the failure diagnosis of the second inverter when the current is not supplied to the plurality of semiconductor switching elements of the first inverter in the first drive system.

2. The electric motor control device according to claim 1, wherein the first micro-control unit is configured to execute the failure diagnosis of the first inverter prior to the failure diagnosis of the second inverter to be executed by the second micro-control unit.

3. The electric motor control device according to claim 2, wherein the second micro-control unit is configured to execute the failure diagnosis of the second inverter when the second micro-control unit is notified of a result of the failure diagnosis of the first inverter from the first micro-control unit.

4. The electric motor control device according to claim 3, wherein the second micro-control unit is configured to execute the failure diagnosis of the second inverter when the second micro-control unit is not notified of the result of the failure diagnosis of the first inverter from the first micro-control unit even if a predetermined waiting time elapses after activation.

5. The electric motor control device according to claim 1, wherein the second micro-control unit is configured to execute the failure diagnosis of the second inverter prior to the failure diagnosis of the first inverter to be executed by the first micro-control unit.

6. The electric motor control device according to claim 5, wherein the first micro-control unit is configured to execute the failure diagnosis of the first inverter when the first micro-control unit is notified of a result of the failure diagnosis of the second inverter from the second micro-control unit.

7. The electric motor control device according to claim 6, wherein the first micro-control unit is configured to execute the failure diagnosis of the first inverter when the first micro-control unit is not notified of the result of the failure diagnosis of the second inverter from the second micro-control unit even if a predetermined waiting time elapses after activation.

8. The electric motor control device according to claim 1, wherein
the first drive system further includes a relay formed by a semiconductor switching element that opens or closes an electric path connecting the first inverter and the electric motor, and
the first micro-control unit is configured to execute a failure diagnosis of the relay together when operating a semiconductor switching element on an upper stage among the plurality of semiconductor switching elements of the first inverter for a predetermined time to execute the failure diagnosis of the first inverter.

9. The electric motor control device according to claim 1, wherein
the second drive system further includes a relay formed by a semiconductor switching element that opens or closes an electric path connecting the second inverter and the electric motor, and
the second micro-control unit is configured to execute a failure diagnosis of the relay together when operating a semiconductor switching element on an upper stage among the plurality of semiconductor switching elements of the second inverter for a predetermined time to execute the failure diagnosis of the second inverter.

10. The electric motor control device according to claim 1, wherein
the first drive system further includes a power supply relay that opens or closes an electric path connecting the first inverter and a positive terminal of a DC power supply, and a capacitor arranged on a branch path that branches off from an electric path connecting the power supply relay and the positive terminal of the DC power supply and that is connected to a negative terminal of the DC power supply, and
the first micro-control unit is configured to turn off the power supply relay to execute the failure diagnosis of the first inverter in accordance with an inter-terminal voltage of the capacitor and an inter-terminal voltage of the electric motor.

11. The electric motor control device according to claim 1, wherein
the second drive system further includes a power supply relay that opens or closes an electric path connecting the second inverter and a positive terminal of a DC power supply, and a capacitor arranged on a branch path that branches off from an electric path connecting the power supply relay and the positive terminal of the DC power supply and that is connected to a negative terminal of the DC power supply, and
the second micro-control unit is configured to turn off the power supply relay to execute the failure diagnosis of the second inverter in accordance with an inter-terminal voltage of the capacitor and an inter-terminal voltage of the electric motor.

12. The electric motor control device according to claim 1, wherein the second micro-control unit is configured to cause an operation mode to transition to a low power mode when a result of the failure diagnosis of the first inverter notified from the first micro-control unit is normal.

13. The electric motor control device according to claim 1, wherein the first micro-control unit and the second micro-control unit are configured to execute the failure diagnoses of the first inverter and the second inverter, respectively, following activation of the first drive system and the second drive system.

14. An electric motor control method for controlling the electric motor by an electric motor control device including:
a first drive system including a first micro-control unit and a first inverter composed of a plurality of semiconductor switching elements, the first micro-control unit being configured to control the semiconductor switching elements of the first inverter and convert a DC current into an AC current to control driving of the electric motor including windings of a plurality of phases and to individually supply a current to the plurality of semiconductor switching elements of the first inverter to execute a failure diagnosis of the first inverter, and
a second drive system including a second micro-control unit and a second inverter composed of a plurality of semiconductor switching elements, the second inverter being connected to an electric path connecting the first inverter and the electric motor, the second micro-control unit being configured to, when a failure occurs in the first drive system, control the semiconductor switching elements of the second inverter and convert a DC current into an AC current to control driving of the electric motor and to individually supply a current to the plurality of semiconductor switching elements of the second inverter to execute a failure diagnosis of the second inverter, the electric motor control method comprising:
executing, by the first micro-control unit, the failure diagnosis of the first inverter when the current is not supplied to the plurality of semiconductor switching elements of the second inverter in the second drive system; and
executing, by the second micro-control unit, the failure diagnosis of the second inverter when the current is not supplied to the plurality of semiconductor switching elements of the first inverter in the first drive system.
